(19) United States
(12) Patent Application Publication
(10) Pub. No.: US 2025/0238047 A1
(43) Pub. Date: Jul. 24, 2025

(54) SEMICONDUCTOR DEVICE, ENCRYPTION DEVICE, AND ELECTRONIC APPLIANCE

(71) Applicant: Sharp Semiconductor Innovation Corporation, Tenri City (JP)

(72) Inventor: Haruhiko SHIGEMASA, Tenri City (JP)

(21) Appl. No.: 18/975,067

(22) Filed: Dec. 10, 2024

(30) Foreign Application Priority Data
Jan. 23, 2024 (JP) 2024-008078

(51) Int. Cl. G05F 1/575; G06F 1/26; G06F 7/58; H03K 3/84

(52) U.S. Cl. CPC G05F 1/575; G06F 1/26; G06F 7/588; H03K 3/84

(57) ABSTRACT

A semiconductor device supplies power to an encryption circuit. The semiconductor device comprises a voltage generator including a series regulator and a shunt regulator, and a controller configured to randomly switch the shunt regulator between an ON state and an OFF state.

### CROSS-REFERENCE TO RELATED APPLICATION

The present application claims priority from Japanese Application JP2024-008078, the content of which is hereby incorporated by reference into this application.

### BACKGROUND OF THE INVENTION

### 1. Field of the Invention

The present disclosure relates to a semiconductor device, an encryption device, and an electronic appliance.

### 2. Description of the Related Art

Side-channel attacks exploit leakage of information from semiconductor devices.

Specifically known techniques of the side-channel attacks include the power analysis attack and the electromagnetic-field analysis attack. The power analysis attack involves analyzing variations in power consumption, so as to estimate secret information. The electromagnetic-field analysis attack involves analyzing variations in an electromagnetic field reflected from a target device, so as to estimate secret information.

The power analysis attack exploits a fact that power consumption of an encryption circuit that performs at least one of encryption or decryption of data is correlated with details of processing performed by the encryption circuit. The power analysis attack involves measuring temporal variations in power consumption during an operation of the circuit and processing a waveform of the temporal variations, so as to estimate secret information such as a secret key. The power analysis attack includes such known techniques as: simple power analysis (SPA) to analyze one or a plurality of measured power waveforms so as to estimate, for example, an encryption key; differential power analysis (DPA) to statistically process a difference between the power waveforms so as to estimate, for example, an encryption key; and correlation power analysis (CPA) to calculate a correlation value of the Hamming distance to an estimated key so as to estimate, for example, an encryption key.

The electromagnetic-field analysis attack can analyze local power variations of a semiconductor device through an electromagnetic field. That is why, in recent years, the electromagnetic-field analysis attack has posed a more serious threat than the power analysis attack. The electromagnetic-field analysis attack can perform the analysis from data obtained with, for example, an electromagnetic field probe. Simple electromagnetic analysis (SEMA) is a technique to use an electromagnetic field instead of power for the simple power analysis. Differential electromagnetic analysis (DEMA) is a technique to use an electromagnetic field instead of power for the differential power analysis. Correlation electromagnetic analysis (CEMA) is a technique to use an electromagnetic field instead of power for the correlation power analysis.

As a countermeasure against the side-channel attacks, STELLAR: A Generic EM Side-Channel Attack Protection through Ground-Up Root-cause Analysis, Debayan Das et al., School of Electrical and Computer Engineering et al., Jun. 21, 2019 discloses a technique; that is, a shunt LDO is connected to an encryption circuit so as to maintain a current supplied from a power supply line and reduce leakage of side-channel information. The LDO, which is an abbreviation of low drop out, is a kind of a regulator.

### SUMMARY OF THE INVENTION

The technique disclosed in STELLAR: A Generic EM Side-Channel Attack Protection through Ground-Up Root-cause Analysis, Debayan Das et al., School of Electrical and Computer Engineering et al., Jun. 21, 2019 might not provide sufficient security against electromagnetic-field analysis attacks. This is because variations in the current value of a local portion included in the shunt LDO and operating to maintain a consumed current might be the side-channel information. Examples of a combination of the local portion and the variations in the current value of the local portion include a combination of a shunt resistor and a shunt current flowing through the shunt resistor.

In recent years, electromagnetic field probes have improved in sensitivity. Hence, even if the shunt LDO reduces the variations in the value of the consumed current, the improvement in sensitivity of an electromagnetic field probe might inevitably allow such secret information as an encryption key to be estimated from local variations in the electromagnetic field of the semiconductor device.

A semiconductor device according to an aspect of the present disclosure supplies power to an encryption circuit. The semiconductor device includes: a voltage generator including a series regulator and a shunt regulator; and a controller that randomly switches the shunt regulator between an ON state and an OFF state.

An aspect of the present disclosure can provide, for example, a semiconductor device that supplies power to an encryption circuit while achieving a high level of security against both a power analysis attack and an electromagnetic-field analysis attack.

### BRIEF DESCRIPTION OF THE DRAWINGS

FIG. 1 is a block diagram illustrating a schematic configuration of an encryption device according to a first embodiment of the present disclosure;

FIG. 2 is a circuit diagram illustrating a configuration example of a voltage generator according to the first embodiment of the present disclosure;

FIG. 3 is a timing diagram showing an example of a current waveform viewed from a power supply terminal and of a result of analysis by a power analysis attack, the example being observed when a series regulator supplies power to an encryption circuit;

FIG. 4 is a timing diagram showing an example of a current waveform viewed from the power supply terminal, the example being observed when a shunt regulator supplies power to the encryption circuit;

FIG. 5 is a timing diagram showing an example of a shunt current waveform and of a result of analysis by an electromagnetic-field analysis attack, the example being observed when the shunt regulator supplies power to an encryption circuit;

FIG. 6 is a timing diagram showing an example of a current waveform viewed from a power supply terminal and of a result of analysis by a power analysis attack, the example being observed when a semiconductor device according to the first embodiment of the present disclosure supplies power to an encryption circuit;

FIG. 7 is a timing diagram showing an example of a shunt current waveform and of a result of analysis by an electromagnetic-field analysis attack, the example being observed when the semiconductor device according to the first embodiment of the present disclosure supplies power to the encryption circuit;

FIG. 8 is a circuit diagram illustrating a configuration example of a random number generating circuit;

FIG. 9 shows a circuit diagram illustrating a configuration example of a random pattern generating circuit, and a timing diagram of a signal output from the random pattern generating circuit;

FIG. 10 shows a circuit diagram illustrating a configuration example of a controller, and a timing diagram of a signal output from the controller;

FIG. 11 is a block diagram illustrating a schematic configuration of an encryption device according to a second embodiment of the present disclosure;

FIG. 12 is a circuit diagram illustrating a configuration example of a voltage generator according to the second embodiment of the present disclosure; and

FIG. 13 is a block diagram illustrating a schematic configuration of an electronic appliance according to a third embodiment of the present disclosure.

### DETAILED DESCRIPTION OF THE INVENTION

Described below will be embodiments of the present disclosure. For convenience in description, like reference signs designate members having identical functions throughout the embodiments. These members might not be elaborated upon repeatedly.

### First Embodiment

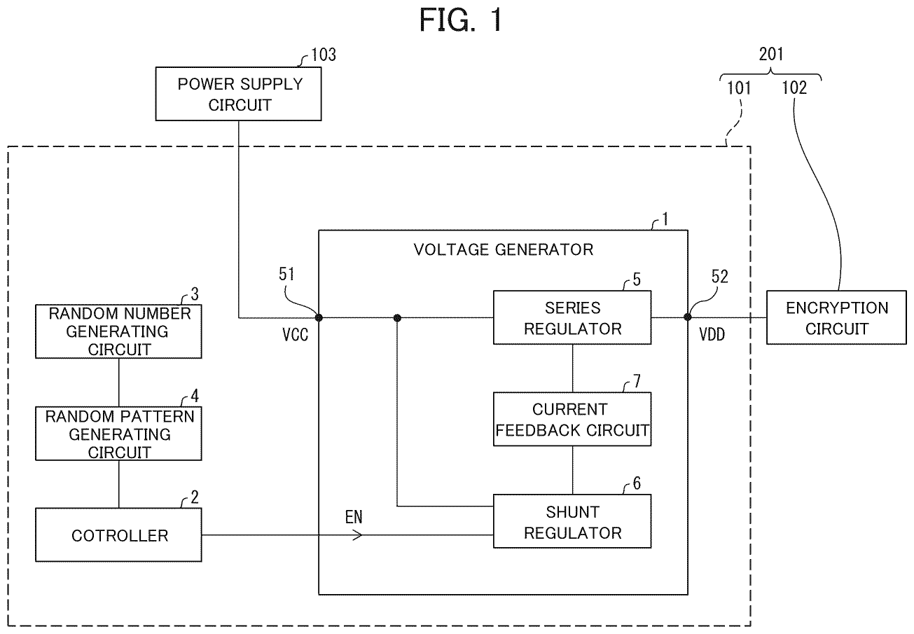

FIG. 1 is a block diagram illustrating a schematic configuration of an encryption device 201 according to a first embodiment of the present disclosure. The encryption device 201 includes: a semiconductor device 101; and an encryption circuit 102. The encryption circuit 102 is suppled with power by the semiconductor device 101. The encryption circuit 102 performs at least one of encryption or decryption of data. That is, the encryption circuit 102 may perform: either encryption or decryption of data; or both encryption and decryption of data. The semiconductor device 101 is included in the scope of the present disclosure, and the encryption device 201 is also included in the scope of the present disclosure.

As to the encryption circuit 102, a value of a current flowing through at least a portion of the semiconductor device 101 varies depending on how the encryption circuit 102 operates. The variations in the value of the current can act as side-channel information.

The semiconductor device 101 supplies power to the encryption circuit 102 that performs at least one of the decryption or the encryption of the data. The semiconductor device 101 includes: a voltage generator 1; a controller 2; a random number generating circuit 3; and a random pattern generating circuit 4.

The voltage generator 1 includes: a series regulator 5; a shunt regulator 6; a current feedback circuit 7; a power supply terminal 51; and an output terminal 52. The controller 2 randomly switches the shunt regulator 6 between an ON state and an OFF state.

The random in this embodiment is preferably true random; however, the random may also be pseudo random achieved by a known technique. The random number in this embodiment is preferably a true random number; however, the random number may also be pseudo random number achieved by a known technique.

The series regulator 5 has one end connected to the power supply terminal 51. The series regulator 5 has an other end connected to the output terminal 52. The shunt regulator 6 has one end connected between the power supply terminal 51 and the series regulator 5. The shunt regulator 6 has an other end connected to the controller 2. The current feedback circuit 7 is connected between the series regulator 5 and the shunt regulator 6. The power supply terminal 51 is connected to a not-shown power supply. The output terminal 52 is connected to the encryption circuit 102.

The series regulator 5 and the shunt regulator 6 operate to convert a voltage (a voltage value VCC), which is input from the power supply circuit 103 to the power supply terminal 51, into a voltage (a voltage value VDD) to be output from the output terminal 52. The series regulator 5 is, for example, a series LDO, and the shunt regulator 6 is, for example, a shunt LDO. The encryption circuit 102 receives the voltage (the voltage value VDD) output from the output terminal 52.

When the shunt regulator 6 is in the ON state, the current feedback circuit 7 supplies the shunt regulator 6 with a current corresponding to the current output from the series regulator 5.

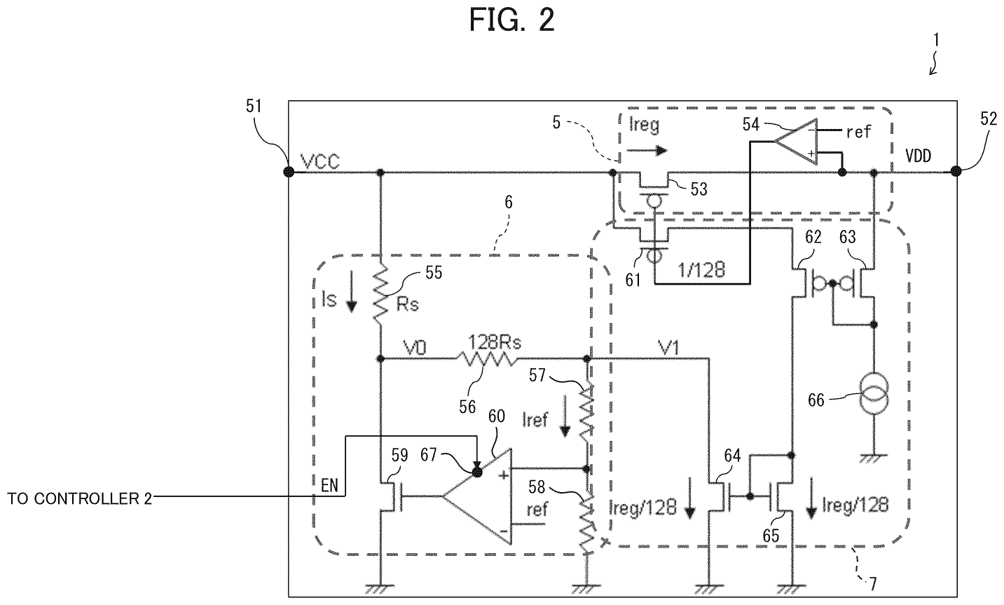

FIG. 2 is a circuit diagram illustrating a configuration example of the voltage generator 1 according to the first embodiment of the present disclosure. The series regulator 5 includes: a transistor 53; and an operational amplifier 54. The shunt regulator 6 includes: a shunt resistor 55; resistors 56 to 58; a transistor 59; and an operational amplifier 60. The current feedback circuit 7 includes: transistors 61 to 65; and a current source 66.

Described below will be a specific example of how the controller 2 randomly switches the shunt regulator 6 between the ON state and the OFF state. The controller 2 outputs a signal serving as an enable signal EN that randomly switches between HIGH and LOW, and supplies the enable signal EN to an enable terminal 67 of the operational amplifier 60. If the enable signal EN supplied to the enable terminal 67 is HIGH, the operational amplifier 60 is enabled, and the shunt regulator 6 turns ON. If the enable signal EN supplied to the enable terminal 67 is LOW, the operational amplifier 60 is disabled, and the shunt regulator 6 turns OFF.

As can be seen, the controller 2 may randomly switch the operational amplifier 60 provided to the shunt regulator 6 between the enable and the disable, so as to randomly switch the shunt regulator 6 between the ON state and the OFF state.

When the shunt regulator 6 is in the ON state, the shunt regulator 6 returns a shunt current stored in the shunt regulator 6 and stays balanced in accordance with a current flowing from the transistor 53 of the series regulator 5. Thus, the voltage generator 1 carries out an operation to maintain constant the current value viewed from the power supply terminal 51. When the shunt regulator 6 is in the OFF state, only the series regulator 5 operates.

When the shunt regulator 6 randomly switches between the ON state to the OFF state, both the current value viewed from the power supply terminal 51 and the shunt current value vary at random. Such a feature allows the semiconductor device 101 to supply power to an encryption circuit while achieving a high level of security against both the power analysis attack and the electromagnetic-field analysis attack.

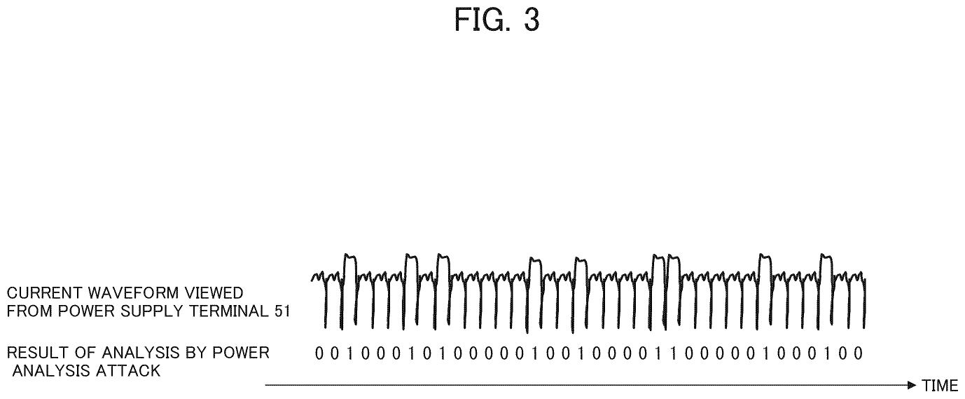

FIG. 3 is a timing diagram showing an example of a current waveform viewed from the power supply terminal 51 and of a result of analysis by the power analysis attack. The example is observed when the series regulator 5 supplies power to the encryption circuit 102.

When the series regulator 5 supplies power to the encryption circuit 102, the current value viewed from the power supply terminal 51 varies depending on how the encryption circuit 102 operates. In other words, the current waveform observed from the power supply terminal 51 shows a pattern corresponding to a secret key. Hence, when the series regulator 5 supplies power to the encryption circuit 102, the secret key can be estimated by the power analysis attack. As a result of the analysis by the power analysis attack, a pattern of 0 and 1 that matches the secret key is obtained as illustrated in FIG. 3.

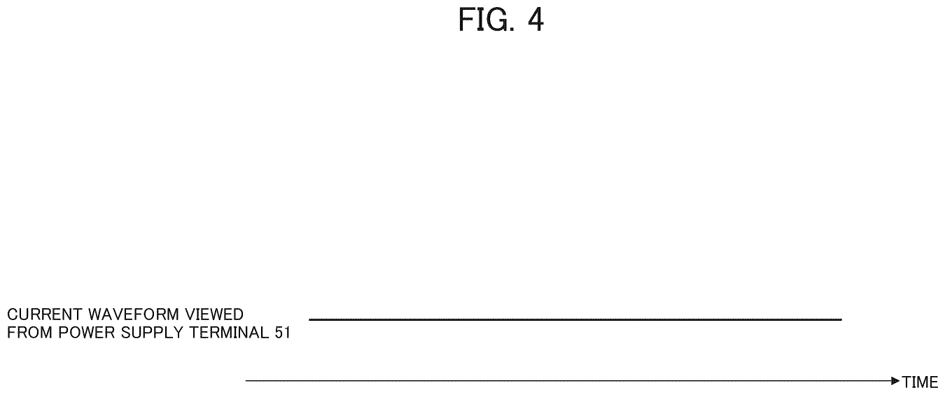

FIG. 4 is a timing diagram showing an example of a current waveform viewed from the power supply terminal 51. The example is observed when the shunt regulator 6 supplies power to the encryption circuit 102.

When the shunt regulator 6 supplies power to the encryption circuit 102, the shunt effect makes infinitely constant the current value viewed from the power supply terminal 51. Such a feature makes it difficult for the power analysis attack to estimate the secret key.

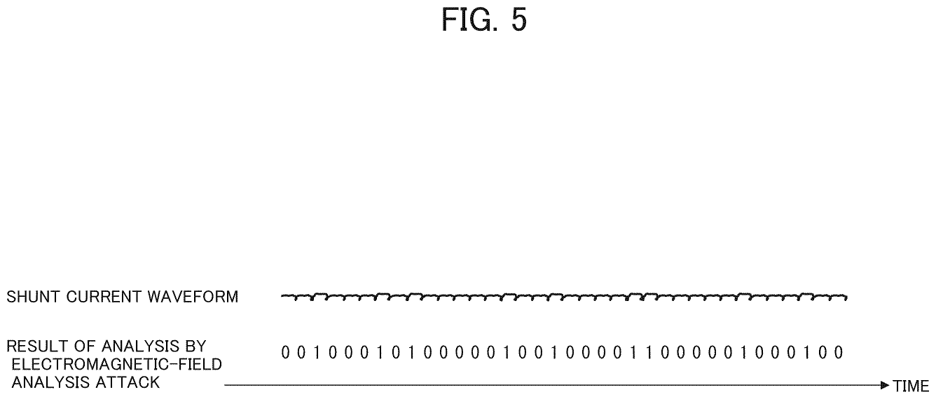

FIG. 5 is a timing diagram showing an example of a shunt current waveform and of a result of analysis by an electromagnetic-field analysis attack. The example is observed when the shunt regulator 6 supplies power to the encryption circuit 102.

When the shunt regulator 6 supplies power to the encryption circuit 102, the current waveform of the shunt resistor 55 built in the shunt regulator 6 slightly shows a pattern corresponding to the secret key. Hence, when the shunt regulator 6 supplies power to the encryption circuit 102, data on the current waveform of the shunt resistor 55 is obtained with a highly sensitive electromagnetic field probe. That is why the secret key can be estimated by the electromagnetic-field analysis attack. As a result of the analysis by the electromagnetic-field analysis attack, a pattern of 0 and 1 that matches the secret key is obtained as illustrated in FIG. 5.

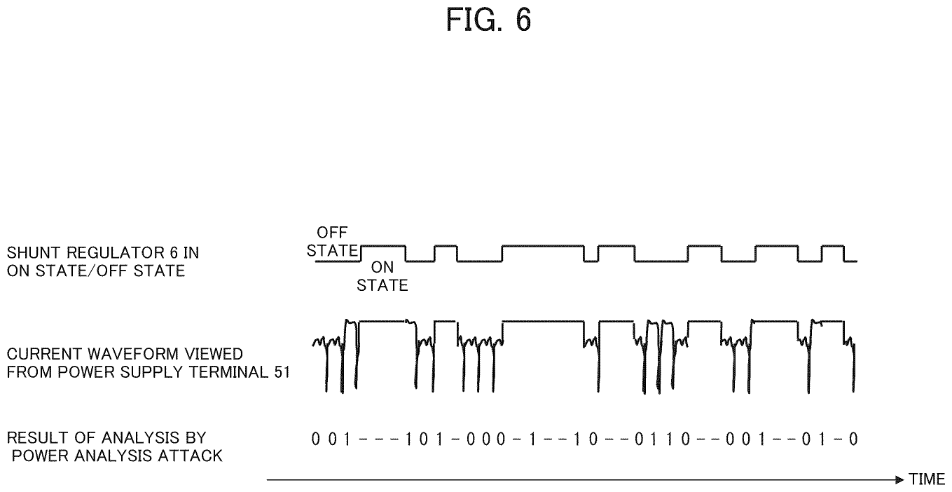

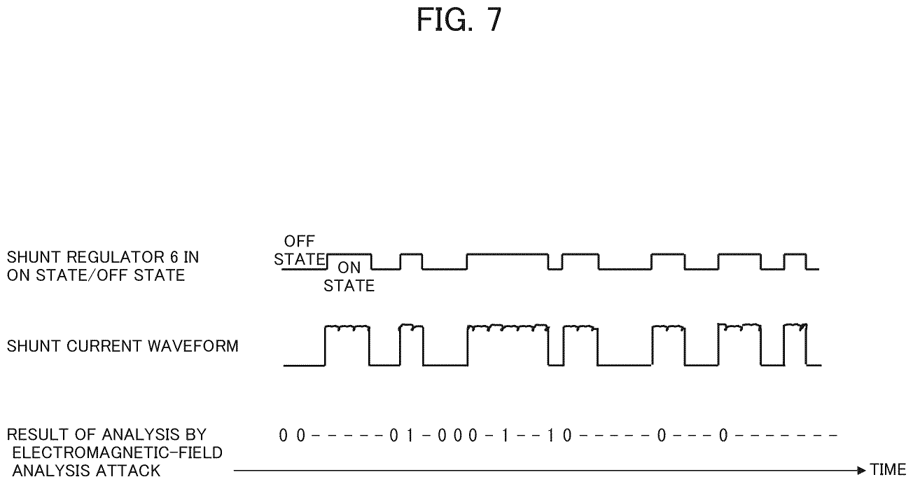

FIG. 6 is a timing diagram showing an example of a current waveform viewed from the power supply terminal 51 and of a result of analysis by the power analysis attack. The example is observed when the semiconductor device 101 supplies power to the encryption circuit 102. FIG. 7 is a timing diagram showing an example of a shunt current waveform and of a result of analysis by an electromagnetic-field analysis attack. The example is observed when the semiconductor device 101 supplies power to the encryption circuit 102. In FIGS. 6 and 7, the sign “−” denotes that neither 0 nor 1 can be correctly estimated by the analysis.

When the semiconductor device 101 supplies power to the encryption circuit 102, the current waveform viewed from the power supply terminal 51 corresponds to FIG. 3 in a period while the shunt regulator 6 is in the OFF state. When the semiconductor device 101 supplies power to the encryption circuit 102, the current waveform viewed from the power supply terminal 51 is clamped by the shunt current in a period while the shunt regulator 6 is in the ON state.

The viewpoints (1) to (3) below show why, when the semiconductor device 101 supplies power to the encryption circuit 102, it is difficult for the power analysis attack to estimate the secret key from the current waveform viewed from the power supply terminal 51.

(1) While the shunt regulator 6 is in the ON state and the OFF state, the current value viewed from the power supply terminal 51 varies in large degree.

(2) Every time the semiconductor device 101 supplies power to the encryption circuit 102, the current waveform viewed from the power supply terminal 51 varies. When such a current waveform is traced multiple times, details of information that can be obtained vary for every trace, and, thus, the information is hardly valuable as the side-channel information.

(3) When the semiconductor device 101 supplies power to the encryption circuit 102, the current waveform viewed from the power supply terminal 51 corresponds to information; that is, the secret key with a portion of information dropped out.

The viewpoints (A) and (B) below show why, when the semiconductor device 101 supplies power to the encryption circuit 102, it is difficult for the electromagnetic-field analysis attack to estimate the secret key from the shunt current.

(A) Every time the semiconductor device 101 supplies power to the encryption circuit 102, the shunt current waveform viewed varies. When such a current waveform is traced multiple times, details of information that can be obtained vary for every trace, and thus, the information is hardly valuable as the side-channel information.

(B) When the shunt regulator 6 is in the OFF state, the shunt current does not flow. The shunt current waveform, observed when the semiconductor device 101 supplies power to the encryption circuit 102, corresponds to information; that is, the secret key with a portion of information dropped out.

Described here with reference to equations is a mechanism to maintain constant the current viewed from the power supply terminal 51 when the shunt regulator 6 included in the voltage generator 1 of this application is in the ON state, together with a relationship with the current feedback circuit 7, the shunt regulator 6, and the series regulator 5.

A reference sign ΔV represents a difference between a potential V0 of the resistor 56 toward the shunt resistor 55 and a potential V1 of the resistor 56 toward the transistor 64. A reference sign Rs represents a resistance value of the shunt resistor 55, and a resistance value of the resistor 56 is 128 Rs (128 times as large as the resistance value Rs). A size of the transistor 61 is 1/128 the size of the transistor 53. A reference sign Ireg represents a value of a current flowing through the series regulator 5; in other words, a value of a current flowing through the transistor 53. A value of a current flowing through the transistors 64 and 65 is Ireg/128 (1/128 of the current value Ireg). In these cases, Equation (1) below holds.

$$Δ V = V 0 - V 1 = ( Ireg / 128 ) \times 128 Rs = Ireg \times Rs . \qquad ( 1 )$$

Wherein the current value Ireg is 0, a shunt current Is is obtained by Equation (2) below, using a voltage value VCC.

$$Is = ( VCC - V 1 ) / Rs . \qquad ( 2 )$$

A shunt current Is' is defined in accordance with Equation (3).

$$Is ’ = ( VCC - V 1 - Δ V ) / Rs = ( VCC - V 1 - Rs \times Ireg ) / Rs = ( ( VCC - V 1 ) / Rs ) - Ireg . \qquad ( 3 )$$

With reference to above Equations (2) and (3), Equation (4) holds.

$$Is ’ = Is - Ireg . \qquad ( 4 )$$

As to the semiconductor device 101, when a load current at the current value Ireg flows through the series regulator 5, the value of the shunt current decreases accordingly. In the semiconductor device 101, variations of the current associated with the load current are offset, such that a current value viewed from the power supply terminal 51 can be maintained constant.

The above example describes a case where a current at a current value 1/128 of the current value Ireg is fed back, with reference to Equations (1) to (4). However, the ratio 1/128 may be changed in accordance with the characteristics of the encryption device 201. For example, the ratio may be 1/64. If the ratio is 1/64, the resistance value of the resistor 56 may be 64 Rs (64 times as large as the resistance value Rs).

Commonly, a circuit without any countermeasures against the side-channel attacks has a potential risk that a secret key might be estimated by the power analysis attack. Hence, various countermeasures have been devised. One of these countermeasures is a technique of clamping a power supply voltage with a shunt LDO. This technique has an advantageous effect of reducing current variations that appear to the power supply terminal, which is aimed as a measurement target by the power analysis attack. Such an advantageous effect makes it difficult to estimate the secret key.

However, unlike the power analysis attack, the electromagnetic-field analysis attack can associate variations in either voltage value or current value of a local portion with either electric field variations or magnetic field variations when an electromagnetic field probe is applied to any given portion of the semiconductor chip. Hence, when the electromagnetic field probe is applied to a local portion such as a shunt resistor built in the shunt LDO while the shunt LEO is in operation, the electromagnetic-field analysis attack can observe variations in value of a microcurrent flowing through the shunt resistor. The variations in the value of the microcurrent flowing through the shunt resistor corresponds to the secret key. Thus, the secret key might be estimated from a waveform of the microcurrent. In recent years, electromagnetic field probes have improved in sensitivity. That is why the electromagnetic-field analysis attack has posed a more serious threat than the power analysis attack.

Hence, the semiconductor device 101 controls the ON state and the OFF state of the shunt regulator 6, using, for example, a random pattern signal corresponding to a random number. Such a feature successfully achieves a function of dropping out a portion of information every time from the secret key.

Even if a reflected electromagnetic field signal is analyzed, the signal has very little value as the side-channel information.

For example, if the power analysis attack is attempted from the power supply terminal 51, the side-channel information associated with power variations is disrupted by the random pattern. As a result, even if the power is measured multiple times, the pattern of the secret key is different each time. That is why it is difficult to estimate the secret key.

Furthermore, even if the electromagnetic-field analysis attack obtains variations in current value of a local portion such as the shunt resistor 55, the variations in current value of the randomly operating shunt regulator 6 solely allow the electromagnetic-field analysis attack to obtain information on the secret key with a portion of the information dropped out. Hence, even if a current value is measured multiple times for the local portion, and the resulting information is obtained, the information is also of very little value as the side-channel information. Thus, it is difficult even for the side-channel attacks to estimate the secret key.

The controller 2 may operate the shunt regulator 6 in each of: a first operation mode in which the shunt regulator 6 is maintained in the ON state; and a second operation mode in which the shunt regulator 6 is maintained in the OFF state. The operational amplifier 60 may be fixed to be enabled when the enable signal EN supplied to the enable terminal 67 is fixed HIGH over the entire period of the first operation mode. The operational amplifier 60 may be fixed to be disabled when the enable signal EN supplied to the enable terminal 67 is fixed LOW over the entire period of the second operation mode.

When the encryption circuit 102 operates in a low security mode, the controller 2 may operate the shunt regulator 6 either in the first operation mode or in the second operation mode. When the encryption circuit 102 operates in a high security mode, the controller 2 randomly switches the shunt regulator 6 between the ON state and the OFF state.

When the encryption circuit 102 operates in the low security mode, that is, for example, when the encryption circuit 102 omits either the encryption processing or the encryption processing, the controller 2 does not have to randomly switch the shunt regulator 6 between the ON state and the OFF state. Hence, when the encryption circuit 102 operates in the low security mode, the controller 2 operates the shunt regulator 6 either in the first operation mode or in the second operation mode. Such a feature successfully simplifies the operation of the semiconductor device 101.

The semiconductor device 101 may include: the random number generating circuit 3 that generates a random number; and the random pattern generating circuit 4 that generates a random pattern corresponding to the random number generated by the random number generating circuit 3. The controller 2 may switch the shunt regulator 6 between the ON state and the OFF state in accordance with the random pattern generated by the random pattern generating circuit 4. Thanks to such a feature, the controller 2 can readily switch the shunt regulator 6 randomly between the ON state and the OFF state.

The random number generating circuit 3 is preferably a circuit that generates a random number. However, the random number generating circuit 3 may be a known pseudo random number circuit that generates a pseudo random number.

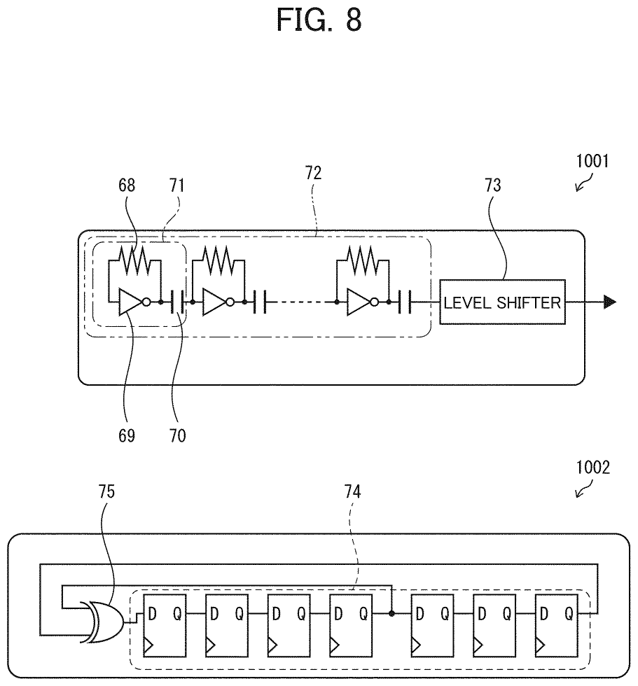

FIG. 8 is a circuit diagram illustrating a configuration example of the random number generating circuit 3. The random number generating circuit 3 may be an analog random number generating circuit such as a self-propelled 1-bit random number generating circuit 1001, or may be an M-sequence generating circuit 1002. An M-sequence length in the M-sequence generating circuit 1002 illustrated in FIG. 8 is obtained as 2⁷−1=127; however, the M-sequence length in the M-sequence generating circuit shall not be limited to 127.

The self-propelled 1-bit random number generating circuit 1001 includes: a circuit 72 including four to six circuits 71 connected in series; and a level shifter 73 connected to an output end of the circuit 72. Each of the circuits 71 includes: a resistor 68; an inverter 69; and a capacitor 70. The M-sequence generating circuit 1002 includes: a shift register 74 including seven D flip-flops connected in series; and an XOR circuit 75 connected to the shift register 74.

The random number generating circuit 3, such as the self-propelled 1-bit random number generating circuit 1001 and the M-sequence generating circuit 1002, can be formed of a known technique, and the details thereof will be limited.

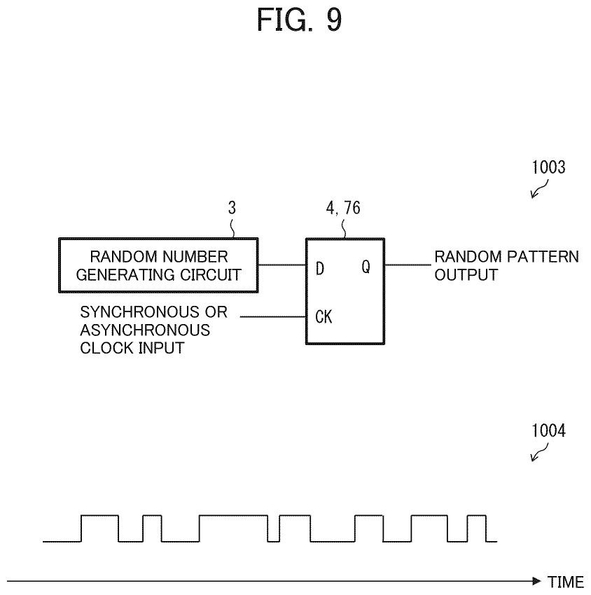

FIG. 9 shows a circuit diagram 1003 illustrating a configuration example of the random pattern generating circuit 4, and a timing diagram 1004 of a signal output from the random pattern generating circuit 4. The random pattern generating circuit 4 includes a D flip-flop 76. The D flip-flop 76 has a D terminal connected to an output end of the random number generating circuit 3. The D flip-flop 76 has a Q terminal that outputs a signal, and the signal is supplied to the controller 2. The D flip-flop 76 has a CK terminal that receives a clock. In accordance with a random number generated by the random number generating circuit 3 and input to the D terminal, the random pattern generating circuit 4 generates a random pattern, and outputs the generated random pattern from the Q terminal to the controller 2.

The clock input to the CK terminal of the D flip-flop 76 may be synchronous to an operation clock of the encryption circuit 102. Operation timing of the random pattern generating circuit 4 may be synchronous to operation timing of the encryption circuit 102. Such a feature eliminates the need for a circuit to generate a clock to be input to the CK terminal of the D flip-flop 76, in addition to a circuit to generate an operation clock of the encryption circuit 102. Hence, the semiconductor device 101 can be formed in a simple configuration.

The clock input to the CK terminal of the D flip-flop 76 may be asynchronous to the operation clock of the encryption circuit 102. The operation timing of the random pattern generating circuit 4 may be asynchronous to the operation timing of the encryption circuit 102.

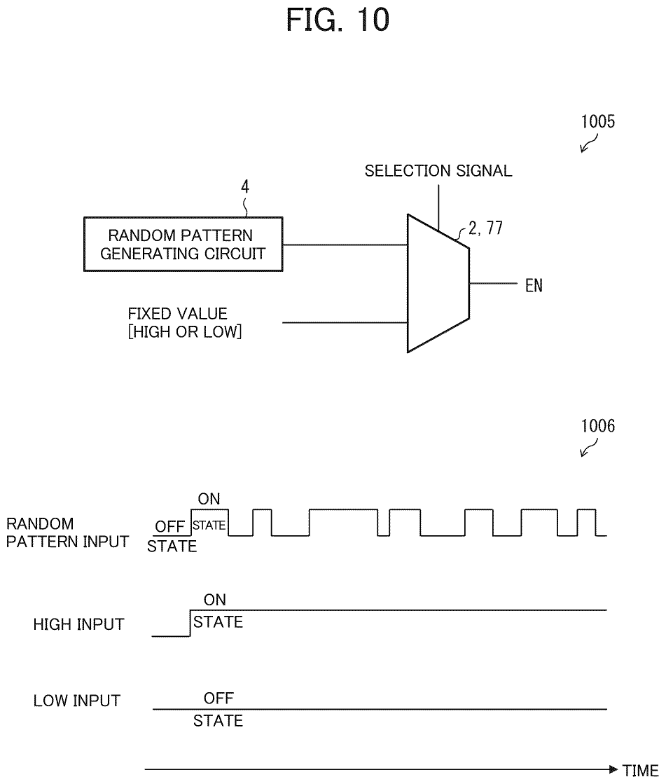

FIG. 10 shows a circuit diagram 1005 illustrating a configuration example of the controller 2, and a timing diagram 1006 of a signal output from the controller 2. The controller 2 includes a multiplexer 77. The multiplexer 77 has a first input end connected to an output end of the random pattern generating circuit 4. The multiplexer 77 has a second input end that receives a signal fixed either HIGH or LOW. The multiplexer 77 receives a selection signal, and determines, in accordance with this selection signal, whether to output either a signal input to the first input end or a signal input to the second input end. The signal output from the multiplexer 77 corresponds to the enable signal EN to be supplied to the enable terminal 67.

As the random pattern input of the timing diagram 1006 shows, the controller 2 outputs a signal serving as the enable signal EN to switch the shunt regulator 6 randomly between the ON state and the OFF state, in accordance with the random pattern input to the first input end of the multiplexer 77. As the HIGH input of the timing diagram 1006 shows, the controller 2 outputs a signal serving as the enable signal EN to operate the shunt regulator 6 in the first operation mode, in accordance with the signal fixed HIGH and input to the second input end of the multiplexer 77. As the LOW input of the timing diagram 1006 shows, the controller 2 outputs a signal serving as the enable signal EN to operate the shunt regulator 6 in the second operation mode, in accordance with the signal fixed LOW and input to the second input end of the multiplexer 77. The timing diagram 1006 partially illustrates both the ON state and the OFF state of the shunt regulator 6 in synchronized timing.

The controller 2 may be configured in the form of either hardware or software.

The shunt regulator 6 may include a shunt resistor 55 a resistance value of which is variable. The shunt resistor 55 is connected to the power supply terminal 51 that receives a voltage to be input to the voltage generator 1. Thanks to such a feature, the value of the shunt current is variable. As a result, it is more difficult for the electromagnetic-field analysis attack to estimate the secret key, thereby successfully providing a higher level of security against the electromagnetic-field analysis attack.

Measures (X) and (Y) are switched at random, which disturbs both of the waveforms of a current viewed from the power supply terminal 51 and a current of a local portion (e.g., the shunt resistor 55). Such a feature can provide the encryption device 201 with a high level of security against both the power analysis attack and the electromagnetic-field analysis attack.

(X): When the shunt regulator 6 is in the ON state, the shunt regulator 6 operates. Hence, the value of the current viewed from the power supply terminal 51 is constant, and the value of the current in the local portion can slightly correspond to how the encryption circuit 102 operates.

(Y): When the shunt regulator 6 is in the OFF state, only the series regulator 5 operates. Hence, the value of the current viewed from the power supply terminal 51 can correspond to how the encryption circuit 102 operates, and the value of the current in the local portion is constant.

### Second Embodiment

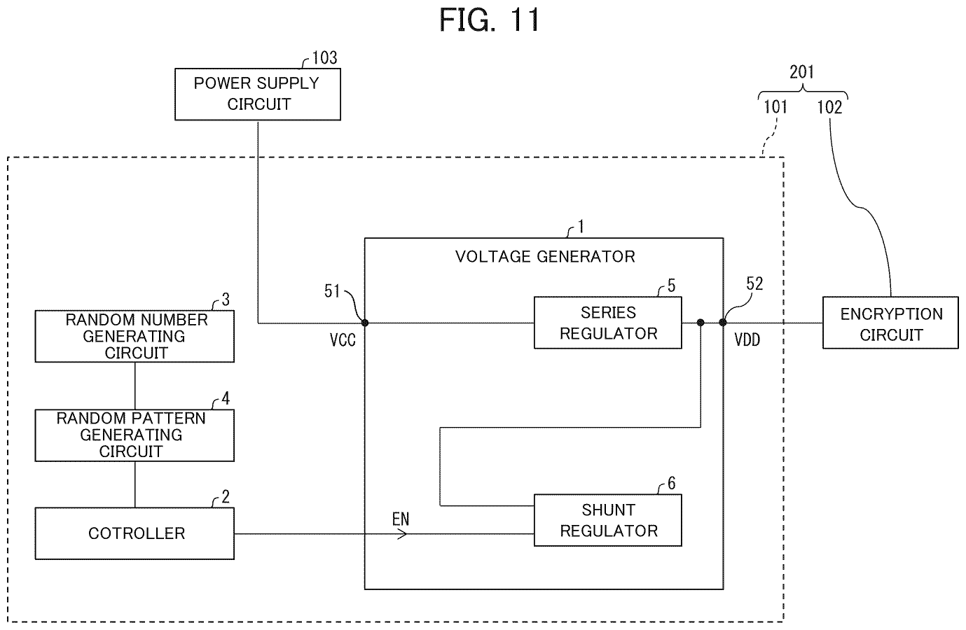

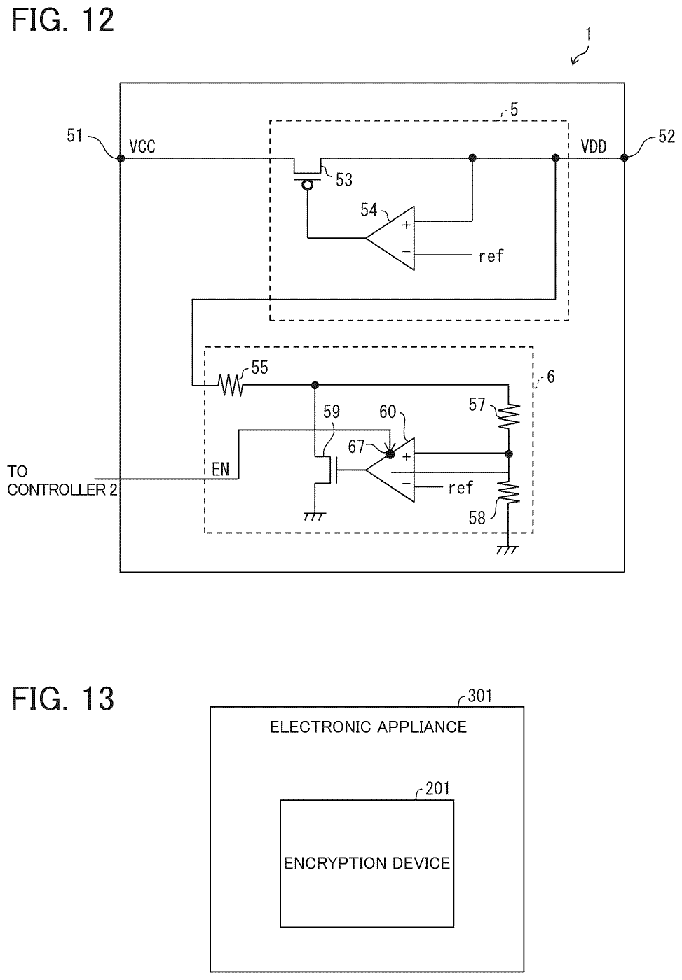

FIG. 11 is a block diagram illustrating a schematic configuration of an encryption device 201 according to a second embodiment of the present disclosure. FIG. 12 is a circuit diagram illustrating a configuration example of the voltage generator 1 according to the second embodiment of the present disclosure. As seen in the second embodiment of the present disclosure, the shunt regulator 6 may be connected to the output end of the series regulator 5. In this case, the shunt regulator 6 may omit the resistor 56 (see FIG. 2).

### Third Embodiment

FIG. 13 is a block diagram illustrating a schematic configuration of an electronic appliance 301 according to a third embodiment of the present disclosure. The electronic appliance 301 including the encryption device 201 is also included in the scope of the present disclosure. Examples of the electronic appliance 301 include: an authentication device (e.g., an IC card and a SIM card), a wireless communications device of a mobile phone; a wireless communications device for satellite communications, and an IoT device for Internet connection. The IC is an abbreviation for integrated circuit. The SIM is an abbreviation for subscriber identity module. The IoT is an abbreviation for internet of things. All devices that handle encryption can be examples of the electronic appliance 301.

### SUMMARY

A semiconductor device according to a first aspect of the present disclosure supplies power to an encryption circuit. The semiconductor device includes: a voltage generator including a series regulator and a shunt regulator; and a controller that randomly switches the shunt regulator between an ON state and an OFF state.

A second aspect of the present disclosure relates to the semiconductor device according to the first aspect. The controller operates the shunt regulator in each of: a first operation mode in which the shunt regulator is maintained in the ON state; and a second operation mode in which the shunt regulator is maintained in the OFF state.

A third aspect of the present disclosure relates to the semiconductor device according to the second aspect. When the encryption circuit operates in a low security mode, the controller operates the shunt regulator either in the first operation mode or in the second operation mode. When the encryption circuit operates in a high security mode, the controller randomly switches the shunt regulator between the ON state and the OFF state.

A fourth aspect of the present disclosure relates to the semiconductor device according to any one of the first to third aspects. The semiconductor device further includes: a random number generating circuit that generates a random number; and a random pattern generating circuit that generates a random pattern corresponding to the ransom number. The controller switches the shunt regulator between the ON state and the OFF state in accordance with the random pattern.

A fifth aspect of the present disclosure relates to the semiconductor device according to the fourth aspect. Operation timing of the random pattern generating circuit is synchronous to operation timing of the encryption circuit.

A sixth aspect of the present disclosure relates to the semiconductor device according to any one of the first to fifth aspects. The voltage generator includes a current feedback circuit configured to supply the shunt regulator with a current when the shunt regulator is in the ON state, the current corresponding to a current output from the series regulator.

A seventh aspect of the present disclosure relates to the semiconductor device according to any one of the first to sixth aspects. The shunt regulator includes a shunt resistor a resistance value of which is variable. The shunt resistor is connected to a terminal that receives a voltage to be input to the voltage generator.

An eighth aspect of the present disclosure relates to the semiconductor device according to any one of the first seventh aspects. The shunt regulator is connected to an output end of the series regulator.

An encryption device according to a ninth aspect of the present disclosure includes: the semiconductor device according to any one of the first to eighth aspects; and an encryption circuit suppled with power by the semiconductor device.

An electronic appliance according to a tenth aspect of the present disclosure includes the encryption device according to the ninth aspect.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Furthermore, the technical aspects disclosed in each embodiment may be combined to achieve a new technical feature.

While there have been described what are at present considered to be certain embodiments of the present disclosure, it will be understood that various modifications may be made thereto, and it is intended that the appended claims cover all such modifications as fall within the true spirit and scope of the present disclosure.

What is claimed is:

1. A semiconductor device that supplies power to an encryption circuit, the semiconductor device comprising:
a voltage generator including a series regulator and a shunt regulator; and
a controller configured to randomly switch the shunt regulator between an ON state and an OFF state.

2. The semiconductor device according to claim 1,
wherein the controller operates the shunt regulator in each of: a first operation mode in which the shunt regulator is maintained in the ON state; and a second operation mode in which the shunt regulator is maintained in the OFF state.

3. The semiconductor device according to claim 2,
wherein, when the encryption circuit operates in a low security mode, the controller operates the shunt regulator either in the first operation mode or in the second operation mode, and
when the encryption circuit operates in a high security mode, the controller randomly switches the shunt regulator between the ON state and the OFF state.

4. The semiconductor device according to claim 1, further comprising:
a random number generating circuit configured to generate a random number; and
a random pattern generating circuit configured to generate a random pattern corresponding to the ransom number,
wherein the controller switches the shunt regulator between the ON state and the OFF state in accordance with the random pattern.

5. The semiconductor device according to claim 4,
wherein operation timing of the random pattern generating circuit is synchronous to operation timing of the encryption circuit.

6. The semiconductor device according to claim 1,
wherein the voltage generator includes a current feedback circuit configured to supply the shunt regulator with a current when the shunt regulator is in the ON state, the current corresponding to a current output from the series regulator.

7. The semiconductor device according to claim 1,
wherein the shunt regulator includes a shunt resistor a resistance value of which is variable, the shunt resistor being connected to a terminal that receives a voltage to be input to the voltage generator.

8. The semiconductor device according to claim 1,
wherein the shunt regulator is connected to an output end of the series regulator.

9. An encryption device, comprising:
the semiconductor device according to claim 1; and
an encryption circuit suppled with power by the semiconductor device.

10. An electronic appliance including the encryption device according to claim 9.
